(19) United States
(12) Patent Application Publication
(10) Pub. No.: US 2007/0278671 A1
(43) Pub. Date: Dec. 6, 2007

(54) Ball grind array package structure

(75) Inventor: Wen-Jeng Fan, Hsinchu (TW)

Correspondence Address: BIRCH STEWART KOLASCH & BIRCH, PO BOX 747, FALLS CHURCH, VA, 22040-0747, US

(73) Assignee: Powertech Technology Inc., Hsinchu (TW)

(21) Appl. No.: 11/445,158

(22) Filed: Jun. 2, 2006

(51) Int. Cl. H01L 23/48; H01L 23/52; H01L 29/40

(52) U.S. Cl. 257/734

(57) ABSTRACT

An IC package structure of die face up or die face down is provided with adding the occupied area of die-attaching material. The die-attaching layer is distributed the surface of the substrate exposed by a die and configured for absorbing the thermal stress induced from thermal expansion mismatch of materials generated during a board level temperature cycle test.

### BACKGROUND OF THE INVENTION

1. Field of the Invention

The present invention relates to the structure of IC package, and more especially, to the structure of IC package that would improve the solder joint life during board level temperature cycle test.

2. Background of the Related Art

According to the high speed developing of semi-conductor industries, IC component designs of electronic devices tend to develop on high pin counts and multi-functional requirements. And the component outline design will prefer smaller size and lighter. For these reasons, the IC package process faces lots of challenge, for example, high requirements on electrical, thermal and reliability performance, package materials selection, warpage control, and the issue of mechanical strength improvement.

FIG. 1 is a top-view perspective schematic diagram illustrating the package of wBGA (window BGA) in accordance with a prior art. Taking a package of single die as an example, a substrate 100 is provided with a slot 110 and an area range of die-attaching layer 112 on which a die is positioned. Solder balls 114 are distributed at the bottom of the package. Shown in FIG. 2, after IC package process, the package 120 may mount onto a board 130 with SMT process, and perform the board level temperature cycle test to evaluate the board level reliability performance. FIG. 6 is a cross-sectional diagram illustrating the area of die-attaching material in accordance with a prior art. One die 214 and the die-attaching material 112 are positioned on a substrate 100 and covered with a molding compound 220. The die-attaching material 112 is within the area of the die 214. Next, another surface of the substrate 100 has a plurality of conductive pads 222 exposed to a solder resist 224 and solder balls 114 are attached thereon. Furthermore, there are wires 228 electrically connect the die 214 and the conductive pads 222. During testing, the package structure may suffer from thermal stress caused by mismatch of thermal expansion coefficients of different materials. The solder balls 114 are easily subject to crack during the test. The crack will cause resistance of the electrical conduction line to be increased and deteriorate the device function and performance. Accordingly, it is one of important issues to ensure and improve the solder balls integrity.

### SUMMARY OF THE INVENTION

In order to reduce the stress mismatch of package during the board-level temperature cycle test, a package structure is provided with a range of die-attaching material extended to or near to whole surface of the substrate for absorbing thermal mismatch stress.

Accordingly, one embodiment of the present invention is provided with the addition of area occupied by a die-attaching material. The surface of the IC substrate exposed to a die is covered with the die-attaching material.

Accordingly, an IC package structure includes a substrate with a first surface and a second surface opposite to each other. A die is on the first surface and a die-attaching material is distributed on the first surface and between both the first surface and the die. A molding compound covers the first surface and the die, wherein the portion of the die-attaching material is positioned between the molding compound and the first surface.

### BRIEF DESCRIPTION OF THE DRAWINGS

FIG. 1 is a top-view perspective schematic diagram illustrating the IC package of wBGA in accordance with a prior art.

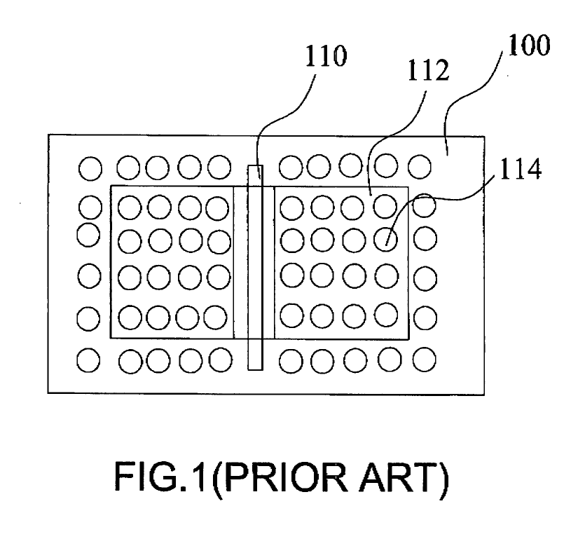

FIG. 2 is a side-view schematic diagram illustrating a sample in the board-level temperature cycle test in accordance with a prior art.

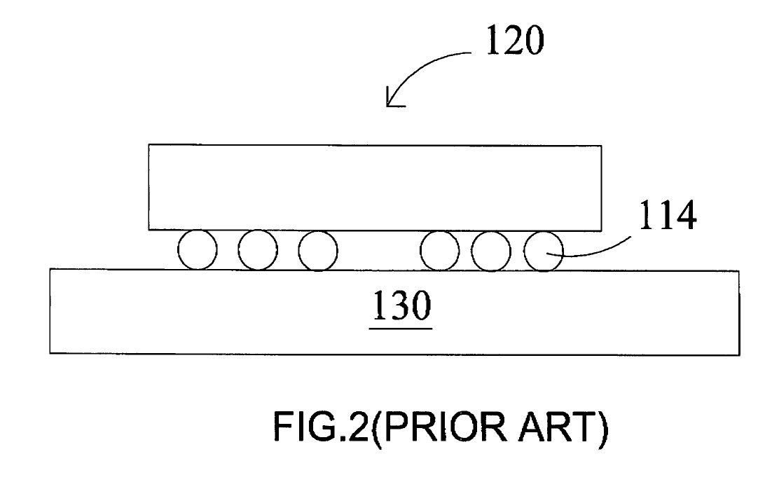

FIG. 3 is a top-view perspective schematic diagram illustrating a block of array of dies in accordance with one embodiment of the present invention.

FIG. 4 is a side-view schematic diagram illustrating a die face down BGA package in accordance with one embodiment of the present invention.

FIG. 5 is a side-view schematic diagram illustrating a die face up BGA package in accordance with one embodiment of the present invention.

FIG. 6 is a cross-sectional diagram illustrating the portion of die-attaching material in accordance with a prior art.

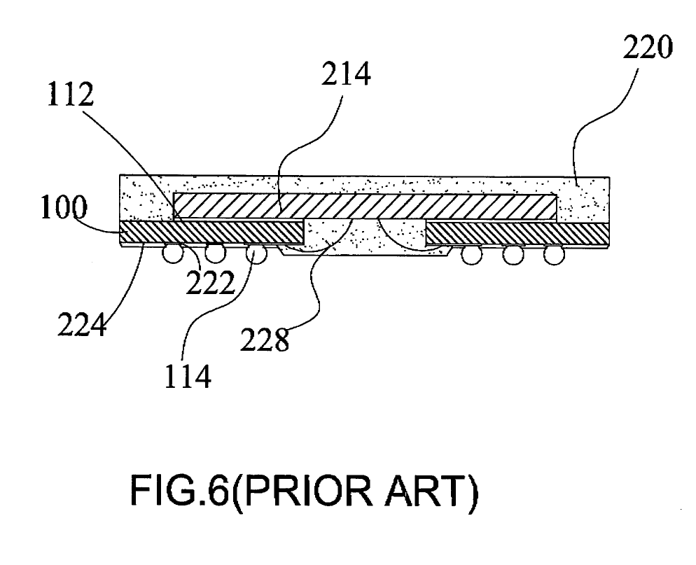

### DETAILED DESCRIPTION OF THE INVENTION

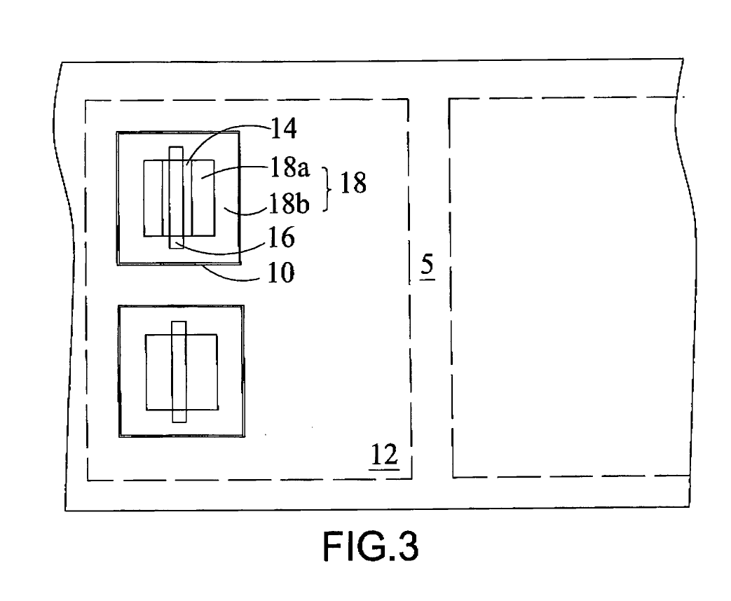

FIG. 3 is a top-view perspective schematic diagram illustrating a block of array of dies in accordance with one embodiment of the present invention. Arrays of dies 12 are in spacing distributed on a carrier 5, each of the arrays of dies 12 has dies 14. In one embodiment, a substrate 10 has slots 16 corresponding to each of the arrays of dies 12. Each of the slots 16 is corresponding to any one of the dies 14 for electrical connection. Next, a die-attaching material 18 is between the dies 14 and the substrate 10. On the other hand, the die-attaching material 18 may be between any two of the dies 14 in one array of dies 12. That is, the portion 18a of the die-attaching material 18 is overlapped with the dies 14, as well as beneath the dies 14. The other portion 18b of the die-attaching material 18 is exposed to the arrays of dies 12 and the dies 14. It is understood that the arrays of dies 12 of the substrate 10 may have the same or different amount of dies 14 or the dies 14 distributed on one surface of the substrate 10. Next, the dies 14 of the arrays of dies 12 may have identical or different functions. Furthermore, the map type of the embodiment is an example for illustration, and does not to limit the present invention.

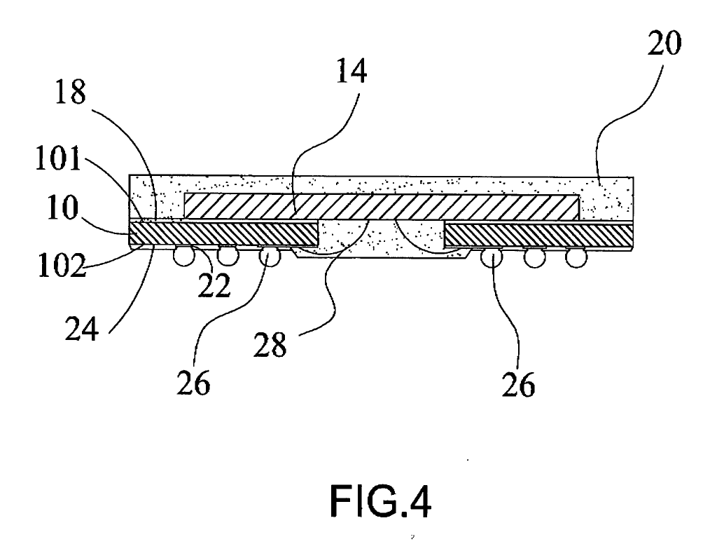

Generally, a packaging process is imposed on an array of dies 12, such as spreading or printing. FIG. 4 is a side-view diagram illustrating an IC package of die in accordance with one embodiment of the present invention. In one embodiment, the die 14 and the die-attaching material 18 are positioned on a first surface 101 of a substrate 10, and the dies 14 and the first surface 101 are covered with a molding compound 20. The die-attaching material 18 coverage area, not limited to die area, but extend to or near to the package edge. The die attach exposed to the dies 14 is distributed between the first surface 101 and the molding compound 20. Next, a second surface 102 of the substrate 10 is opposite to the first surface 101 and has a plurality of conductive pads 22 exposed to a solder resist 24. A plurality of solder balls 26 are positioned on the conductive pads 22. Furthermore, as FBGA (Fine pitch BGA) or FBGA-BOC (Board on Chip) as an example, the substrate 10 is provided with one or more slots and configured for positioning conductive connection wires 28, such as gold wires. The conductive connection wires 28 electrically connect the dies 14 and the conductive pads 22 of the substrate 10.

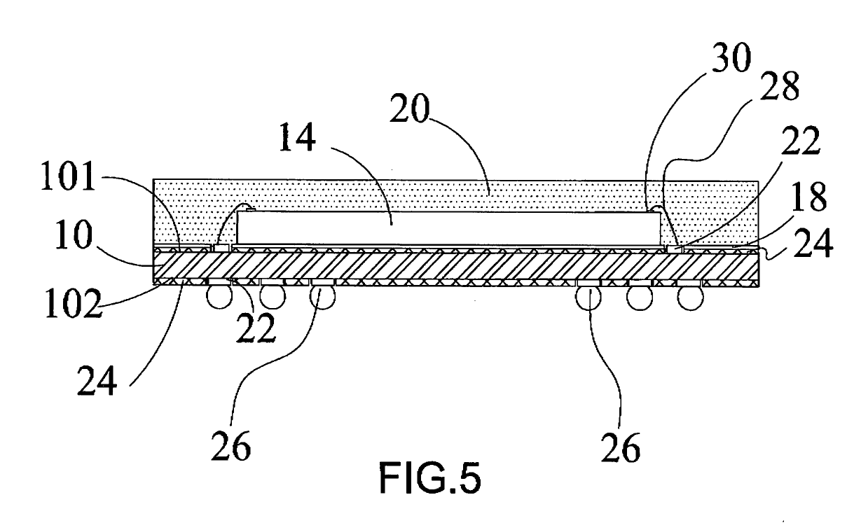

In accordance with the spirits of the present invention, such a package configuration may be applied to die face up or die face down BGA. On application to die face up BGA, the area of the die-attaching material 18 coated is not only to the area of die but also the portion of the exposed first surface 101. Shown in FIG. 5, the solder resist 24 and the exposed conductive pads 22 are positioned on the first surface 101. When the die-attaching material 18 is spread (such as screen printing or film type) on the first surface 101, the conductive pads 22 may be covered by the die-attaching material 18. By wiring steps, the conductive connection wires 28 electrically connect the conductive connection pads 30 of the dies 14 and the conductive pads 22 on the first surface 101.

For application on board level temperature cycle tests of temperature cycle, the die-attaching material 18 with Young's modulus, such as smaller than 1000 MPa, is smaller than other materials with ones in a package structure, for example, the substrate 10 (hard material with one in the range of 200000 to 300000 MPa, flexible material with one smaller than 15000 MPa), the dies 14 (with one in the range of 100000 to 150000 MPa) or the molding compound 20 (with one in the range of 15000 to 25000 MPa). Accordingly, the die-attaching material 18 will absorb thermal stresses caused by the thermal mismatch of different materials, so that the solder balls will be less subject to thermal stress and will improve the solder balls life. Thus, the usage of the coverage area increase of die-attaching material 18 will enhance the life of the package structure during board-level temperature cycle test and the board level reliability.

Table 1 shows one example results come from computer simulationacquired and based on finite element method. Results show the mean life (50% failure rate) would get 48% increased if the die-attaching material area extend to the package edge. It shows the invention would get large improvement on board level temperature cycle results.

TABLE 1
Board level temperature cycle results

| | |
|---|---|
| Die-attaching material area equals to | 1125 cycle |
| die area | |
| Die-attaching material area extends to | 1663 cycle |
| package area | |

Package and board information

| | |
|---|---|
| PKG size | FBGA 9 × 13 mm, 90ball |
| Die size | 6 mm × 10 mm × 0.15 mm(t) |
| SBT thickness | 0.2 mm |
| SBT core | BT |
| Board | 1. Board thickness: 1.6 mm |
| | 2. 6 layers board, 35 um copper for |
| | each layer |
| | 3. Double side mounting |
| Board level temperature cycle test | 1. Temperature profile: |
| condition | −25° C.~125° C. |
| | 2. 30 min/cycle |
| | 3. duration time: 10 minutes/ |
| | 10 minutes |
| | 4. Transition time: 5 minute |

Accordingly, a package structure of die is provided with a die on the first surface of a substrate, a die-attaching material distributed on the first surface and between both the first surface and the die, and a molding compound covering the first surface and the die. A portion of the die-attaching material is positioned between the molding compound and the first surface. Next, a block of die array includes a plurality of arrays of dies distributed in spacing on a substrate, wherein a plurality of dies are distributed in spacing within each of the arrays of dies. A die-attaching material is between the dies and the substrate, and distributed any two dies within each of the arrays of dies.

Although the present invention has been explained in relation to its preferred embodiment, it is to be understood that other modifications and variation can be made without departing the spirit and scope of the invention as hereafter claimed.

What is claimed is:

1. An IC package structure, comprising:
a substrate with a first surface and a second surface opposite to each other;
a die on said first surface;
a die-attaching material distributed on said first surface and between both said first surface and said die; and
a molding compound covering said first surface and said die, wherein a portion of said die-attaching material is positioned between said molding compound and said first surface.

2. The IC package structure according to claim 1, wherein said substrate further comprises a plurality of conductive pads distributed on said second surface.

3. The IC package structure according to claim 2, wherein said substrate further comprises one or more slots through said first surface and said second surface.

4. The IC package structure according to claim 3, further comprising a plurality of bonding wires are through said slot and electrically connected said die and a portion of said conductive pads.

5. The IC package structure according to claim 4, wherein said molding compound further covers said bonding wires.

6. The IC package structure according to claim 2, further comprising a plurality of conductive connecting structures are corresponding to said conductive pads, respectively.

7. The IC package structure according to claim 1, wherein Young's modulus of said die-attaching material is smaller than Young's modulus of said die.

8. The IC package structure according to claim 1, wherein Young's modulus of said die-attaching material is smaller than Young's modulus of said substrate.

9. The IC package structure according to claim 1, wherein Young's modulus of said die-attaching material is smaller than Young's modulus of said molding compound.

10. The IC package structure according to claim 1, wherein the dimension of said first surface is larger than the dimension of said die.

11. The IC package structure according to claim 1, wherein said die has an active side attached to said die-attaching material or said molding compound.

12. A block of die array, comprising:
a plurality of arrays of dies distributed in spacing on a substrate, wherein a plurality of dies are distributed in spacing within each of said arrays of dies; and
a die-attaching material being between said dies and said substrate, and distributed any said two dies within each of said arrays of dies.

13. The block of die array according to claim 12, wherein said substrate has a plurality of slots corresponding to said die array, respectively, and each said slot is corresponding to at least one of said dies.

14. The block of die array according to claim 13, wherein any one of said dies comprises a plurality of metallic conductors through said slot and electrically connected to said substrate.

15. The block of die array according to claim 12, wherein Young's modulus of said die-attaching material is smaller than Young's modulus of said substrate.

16. The block of die array according to claim 12, wherein Young's modulus of said die-attaching material is smaller than Young's modulus of any one of said dies.

17. The block of die array according to claim 12, wherein said substrate is a substrate of ball grid array package.

18. The block of die array according to claim 17, wherein said substrate of ball grid array package further comprises a plurality of conductive pads on a surface opposite to one loaded said dies.

19. The block of die array according to claim 12, further comprising a molding compound covering over said dies and said arrays of dies.

20. The block of die array according to claim 19, wherein said molding compound is attached to said die-attaching material between any two of said dies.
